(19) United States
(12) Patent Application Publication
(10) Pub. No.: US 2012/0299611 A1
(43) Pub. Date: Nov. 29, 2012

(54) PROBE ASSEMBLY

(75) Inventor: CHI-MIN WANG, Tu-Cheng (TW)

(73) Assignee: HON HAI PRECISION INDUSTRY CO., LTD., Tu-Cheng (TW)

(21) Appl. No.: 13/170,343

(22) Filed: Jun. 28, 2011

(30) Foreign Application Priority Data
May 24, 2011 (TW) 100118202

(51) Int. Cl. G01R 1/067

(52) U.S. Cl. 324/755.01

(57) ABSTRACT

A probe assembly includes a probe and an assistant measuring device. The probe includes a main body, a metal tip, a first cable, and a second cable. The assistant measuring device includes a base, a first pole, a second pole, an annular wall, a first input line, and a second input line. The first input line is connected to the first pole. The second input line is connected to the base. When the metal tip is inserted into the hole of the second pole, the metal tip is engaged with the second pole. The main body is engaged with the annular wall. The first cable is connected to the first input line through the metal tip, and the second and first poles. The second cable is connected to the second input line through the main body, the annular wall, and the base.

### BACKGROUND

1. Technical Field

The present disclosure relates to a probe assembly.

2. Description of Related Art

During the testing of electronic devices, an oscillograph is used to test electrical character of the electronic devices to determine whether results of the tests comply with standard specification. In test, a shortest path test is adopted, that is, an anode of a probe of the oscillograph contacts a tested point, and a cathode of the probe contacts a ground point nearest the tested point. However, in testing, the probe needs to contact the tested point, which leads to the probe being affected by magnetic elements around the probe, thereby making signals displayed by the oscillograph distorted.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded view of an embodiment of a probe assembly, the probe assembly includes a probe and an assistant measuring device.

FIG. 2 is an isometric view of the assistant measuring device of FIG. 1, but viewed from another perspective.

FIG. 3 is an assembled, isometric view of the probe assembly of FIG. 1.

### DETAILED DESCRIPTION

The disclosure, including the accompanying drawings in which like references indicate similar elements, is illustrated by way of example and not by way of limitation. It should be noted that references to “an” or “one” embodiment in this disclosure are not necessarily to the same embodiment, and such references mean at least one.

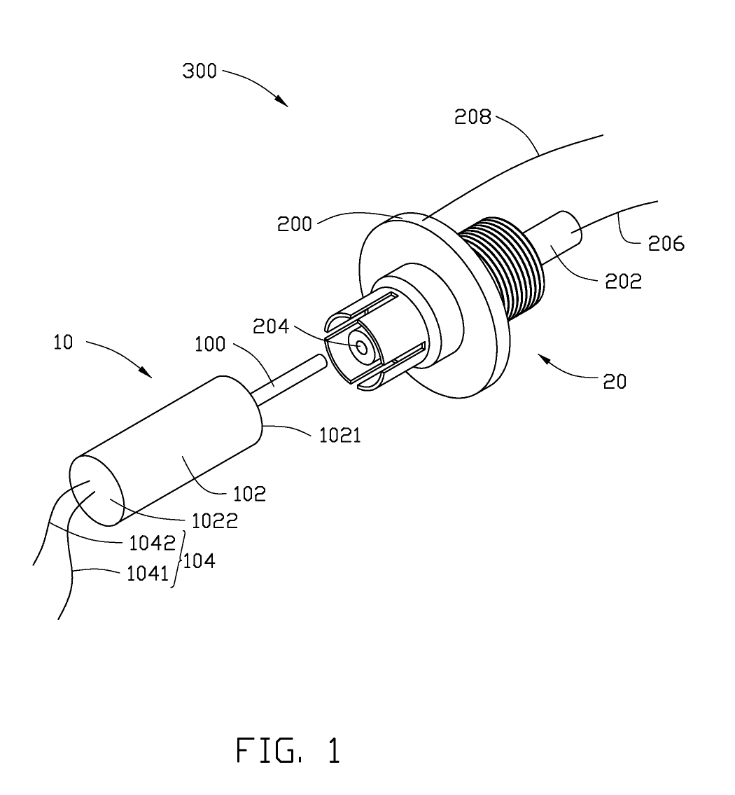

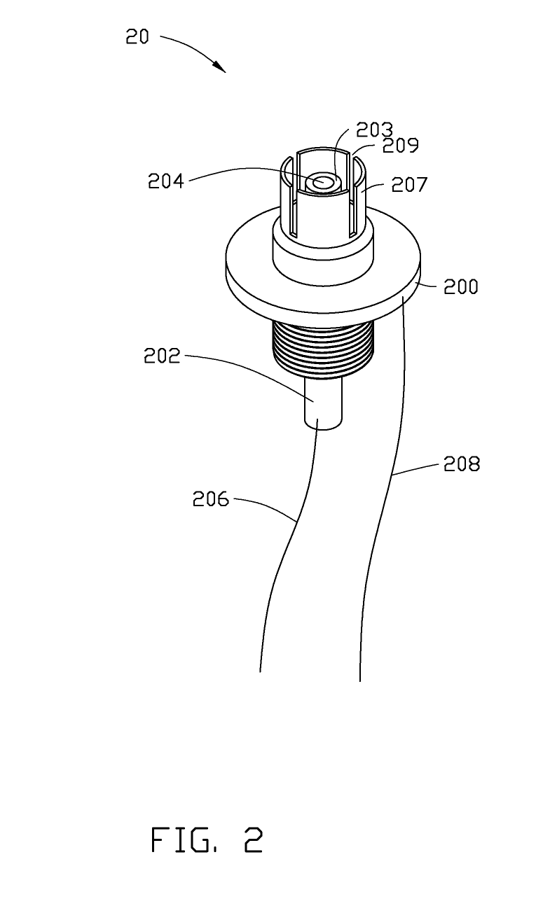

Referring to FIGS. 1 and 2, an embodiment of a probe assembly 300 includes a probe 10 and an assistant measuring apparatus 20. The probe 10 includes a main body 102, a metal tip 100 extending from a first end of the main body 102, and a group of cables 104 extending from a second end 1022 of the main body 102. The metal tip 100 is insulated from the main body 102. The group of cables 104 includes a first cable 1041 and a second cable 1042. A first terminal of the first cable 1041 is connected to the main body 102. A first terminal of the second cable 1042 extends through the main body 102 to be connected to the metal tip 100. Second terminals of the first and second cables 1041 and 1042 are connected an oscillograph (not shown).

The assistant measuring device 20 includes a base 200, a first pole 202 mounted to a bottom of the base 200, a second pole 203 mounted to a top of the base 200, a first input line 206 and a second input line 208. The first pole 202 extends through the base 200 to be electrically connected to the second pole 203. The first and second poles 202 and 203 are both insulated from the base 200. An annular wall 207 perpendicularly extends up from the top of the base 200 and around the second pole 203. The annular wall 207 is electrically connected to the base 200. A hole 204 is axially defined in the second pole 203 to receive the metal tip 100 of the probe 10. The first input line 206 is electrically connected to the first pole 202. The second input line 208 is electrically connected to the base 200. A plurality of cutouts 209 is axially defined in the annular wall 207, to enhance elasticity of the annular wall 207.

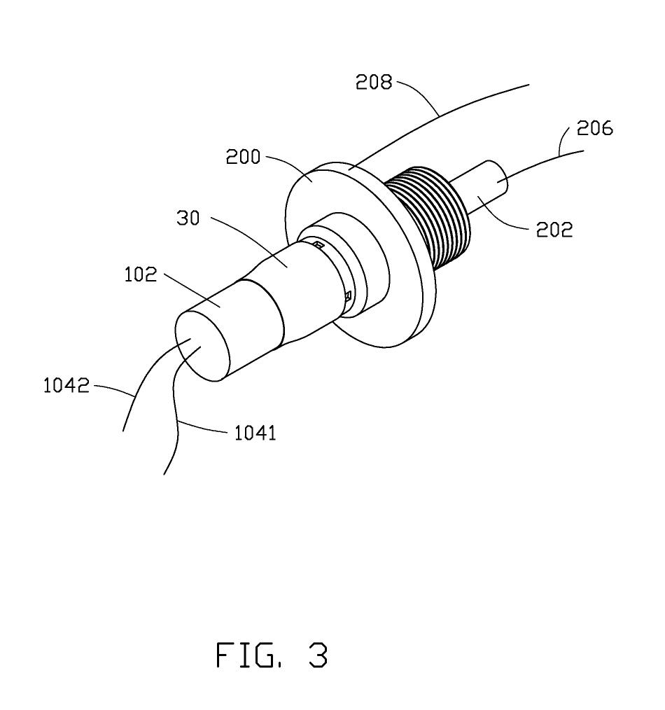

Referring to FIG. 3, in use, the metal tip 100 of the probe 10 is inserted into the hole 204 of the second pole 203 of the assistant measuring device 20. The metal tip 100 is electrically connected to second pole 203. The first end of the main body 102 of the probe 10 is engaged in the annular wall 207 and electrically connected to the annular wall 207. The group of cables 104 is electrically connected to the oscillograph. The first input line 206 is connected to a test point (not shown). The second input line 208 is connected to a ground point nearest the test point. The signal from the test point is transmitted to the oscillograph through the first input line 206, the second pole 202, the first pole 203, the metal tip 100, and the first cable 1041. The signal from the ground point is transmitted to the oscillograph through the second input line 208, the base 200, the annular wall 207, the main body 102, and the second cable 1042.

In the embodiment, the probe assembly 300 further includes a gum cover 30. When the probe 10 is electrically connected to the assistant measuring device 20, the gum cover 30 fits about a junction between the probe 10 and the assistant measuring device 20 to reinforce the connection between the probe 10 and the assistant measuring device 20.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A probe assembly comprising:
a probe comprising:
a main body;
a metal tip mounted to a first end of the main body and insulated from the main body; and
a group of cables comprising a first cable electrically connected to the metal tip and a second cable electrically connected to the main body; and
an assistant measuring device comprising:
a base;
a first pole mounted to a bottom of the base, and insulated from the base;
a second pole mounted to a top of the base and electrically connected to the first pole, and insulated from the base, wherein a hole is axially defined in the second pole;
an annular wall extending from the top of the base and around the second pole;
a first input line electrically connected to the first pole; and
a second input line electrically connected to the base;
wherein when the metal tip is inserted into the hole of the second pole, the metal tip is engaged with the second pole, the main body is engaged with the annular wall, the first cable is electrically connected to the first input line through the metal tip, the second pole, and the first pole, the second cable is electrically connected to the second input line through the main body, the annular wall, and the base.

2. The probe assembly of claim 1, further comprising a gum cover, wherein the gum cover fits about a junction between the probe and the assistant measuring device.

3. The probe assembly of claim 1, wherein a plurality of cutouts is axially defined in the annular wall.
